(19) United States
(12) Patent Application Publication
(10) Pub. No.: US 2010/0186816 A1
(43) Pub. Date: Jul. 29, 2010

(54) SOLAR CELL

(75) Inventors: Sang-Cheol PARK, Seoul (KR); Jung-Gyu NAM, Suwon-si (KR); Jin-Soo MUN, Geoje-si (KR); Sung-Chul KIM, Seoul (KR); Yong-Kweun MUN, Yongin-si (KR); Hong-Seok LEE, Seongnam-si (KR)

Correspondence Address: CANTOR COLBURN, LLP, 20 Church Street, 22nd Floor, Hartford, CT, 06103, US

(73) Assignee: SAMSUNG ELECTRONICS CO., LTD., Suwon-si (KR)

(21) Appl. No.: 12/692,894

(22) Filed: Jan. 25, 2010

(30) Foreign Application Priority Data
Jan. 23, 2009 (KR) 10-2009-0006016
Dec. 8, 2009 (KR) 10-2009-0121378

(51) Int. Cl. H01L 31/00

(52) U.S. Cl. 136/256

(57) ABSTRACT

A solar cell, including a substrate, a first electrode disposed on the substrate, a photoelectric conversion layer disposed on the first electrode, and a second electrode disposed on the photoelectric conversion layer, wherein a grating is disposed on at least one of the first electrode and the second electrode.

### CROSS-REFERENCE TO RELATED APPLICATIONS

This application claims priority to Korean Patent Application No. 10-2009-0006016, filed on Jan. 23, 2009, and Korean Patent Application No. 10-2009-0121378, filed on Dec. 8, 2009, and all the benefits accruing therefrom under 35 U.S.C. §119, the contents of which in their entirety are herein incorporated by reference.

### BACKGROUND

1. Field

One or more embodiments relate to a solar cell having a high energy absorption ratio.

2. Description of the Related Art

As energy issues become increasingly important, much attention has been paid to solar cells as a future alternative energy source. A solar cell is a device that transforms solar energy into electrical energy according to the photoelectric effect. Solar cells are categorized into those formed of silicon semiconductor materials and those formed of compound semiconductor materials. Also, solar cells formed of silicon semiconductor materials are categorized into crystalline-based solar cells and amorphous-based solar cells. When light is incident on a solar cell, electrons and holes are generated in a semiconductor of the solar cell. If electric charges generated upon illumination flow in an electric field caused by a P-N junction, then the electrons move to an N-type semiconductor and the holes move to a P-type semiconductor, thereby causing an electric potential difference between these semiconductors. Accordingly, when a load is connected between the P-type semiconductor and the N-type semiconductor, electric current flows through the load.

### SUMMARY

One or more embodiments include a solar cell having an improved energy absorption ratio.

Additional aspects, features and advantages will be set forth in the description which follows.

To achieve the above and/or other aspects, features and advantages, one or more embodiments includes a solar cell including a substrate; a first electrode disposed on the substrate; a photoelectric conversion layer disposed on the first electrode; and a second electrode disposed on the photoelectric conversion layer, wherein a grating is disposed on at least one of the first electrode and the second electrode.

The grating may have a depth of about 300 nanometers (nm) to about 450 nm.

A period of the grating may be about 900 nm to about 1100 nm.

The photoelectric conversion layer may include a compound semiconductor.

The photoelectric conversion layer may include a material selected from the group consisting of CdTe, CuInSe₂, Cu(In,Ga)Se₂, Cu(In,Ga)(Se,S)₂, Ag(InGa)Se₂, Cu(In,Al)Se₂, CuGaSe₂ and a combination including at least one of the foregoing.

The first electrode may include a transparent conductive oxide.

The first electrode layer may include a material selected from the group consisting of indium tin oxide (“ITO”), indium zinc oxide (“IZO”), ZnO, gallium zinc oxide (“GAZO”), ZnMgO, SnO₂ and mixtures thereof.

The second electrode may include a transparent conductive oxide or a metallic material.

The metallic material may include a material selected from the group consisting of Mo, Al, Cu, Ti, Au, Pt, Ag, Cr and mixtures thereof.

The metallic material may have a thickness of about 0.01 micrometer to about 10 micrometers.

The photoelectric conversion layer may have a tandem structure.

### BRIEF DESCRIPTION OF THE DRAWINGS

These and/or other aspects will become apparent and more readily appreciated from the following description of the embodiments, taken in conjunction with the accompanying drawings in which:

FIG. 1 is a schematic cross-sectional view of an exemplary embodiment of a solar cell;

FIG. 2 is a schematic cross-sectional view of another exemplary embodiment of a solar cell;

FIG. 3 is a cross-sectional view of another exemplary embodiment of a solar cell;

FIG. 4 is a cross-sectional view of another exemplary embodiment of a solar cell;

FIG. 5 is a graph illustrating energy absorption ratio (percent) versus wavelength (nanometers, nm) of an exemplary embodiment of a solar cell having a grating and a solar cell not having a grating;

FIG. 6 is a graph illustrating energy efficiency (percent, %) versus depth (nm) illustrating a relationship between an energy absorption ratio and the depth of a grating included in an exemplary embodiment of a solar cell, according to a period of the grating;

FIGS. 7A to 7E are cross-sectional views illustrating an exemplary embodiment of a method of fabricating a solar cell;

FIG. 8 is a cross-sectional view of another exemplary embodiment of a solar cell;

FIG. 9 is a graph illustrating a light absorption efficiency (percent) according to the thickness of a photoelectric conversion layer (hundreds of nanometers) of solar cells, Exemplary embodiments 2 and 3 having a grating and Exemplary embodiment 1 not having a grating;

FIG. 10 is a graph illustrating a light absorption efficiency (percent) according to a period of a photoelectric conversion layer (nanometers) in an embodiment wherein an inclination angle of a side surface of a grating is 50 degrees;

FIG. 11 is a graph illustrating light absorption efficiency (percent) according to a period of a photoelectric conversion layer (nanometers) in an embodiment in which an inclination angle of a side surface of a grating is 60 degrees; and

FIG. 12 is a graph illustrating light absorption efficiency (percent) according to a period of a photoelectric conversion layer in an embodiment in which an inclination angle of a side surface of a grating is 70 degrees.

### DETAILED DESCRIPTION

Reference will now be made in detail to embodiments, examples of which are illustrated in the accompanying drawings, wherein like reference numerals refer to the like elements throughout. In this regard, the present embodiments may have different forms and should not be construed as being limited to the descriptions set forth herein. Accordingly, the embodiments are merely described below, by referring to the figures, to further explain aspects, features and advantages of the present description.

It will be understood that when an element is referred to as being “on” another element, it can be directly on the other element or intervening elements may be present therebetween. In contrast, when an element is referred to as being “directly on” another element, there are no intervening elements present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting. As used herein, the singular forms “a,” “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another elements as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below. Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, exemplary embodiments of a solar cell will be further described with reference to the accompanying drawings.

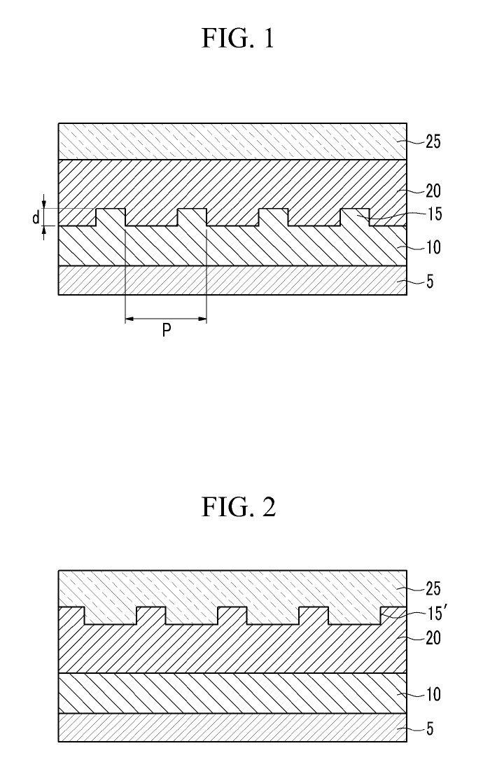

Referring to FIG. 1, an embodiment of a solar cell includes a substrate 5, a first electrode 10 disposed on the substrate 5, a second electrode 25 opposite the first electrode 10, and a photoelectric conversion layer 20 disposed between the first electrode 10 and the second electrode 25. If light is incident on the photoelectric conversion layer 20 via the first electrode 10 or the second electrode 25, electrons and holes are generated, the electrons move to the first electrode, the holes move to the second electrode 25, and then, electric current is conducted through the solar cell. According to the type of the photoelectric conversion layer 20, the electrons may move to the second electrode 25 and the holes may move to the first electrode 10. The higher the energy absorption ratio of the photoelectric conversion layer 20, the higher the luminance efficiency of the solar cell may be. Energy absorption ratio is an amount of energy absorbed by a solar cell with respect to an amount of energy incident upon the solar cell.

For example, the substrate 5 may comprise a ceramic material, such as silicon, glass, or alumina, a plastic material, such as a plastic material having flexible properties, or a metal, such as Al or corrosion resistant steel (“SUS”). The first electrode 10 comprises a transparent conductive oxide. For example, the first electrode 10 may comprise a material selected from a group consisting of indium tin oxide (“ITO”), indium zinc oxide (“IZO”), ZnO, gallium zinc oxide (“GAZO”), ZnMgO, SnO2, and the like and mixtures thereof. The second electrode 25 may comprise a transparent conductive oxide or a thin metallic material. For example, the second electrode 25 may comprise a metallic material selected from a group consisting of Mo, Al, Cu, Ti, Au, Pt, Ag, Cr, and the like and mixtures thereof. The metallic material may be thin and have a thickness of about 0.01 micrometer to about 10 micrometers, specifically about 0.1 micrometer to about 1 micrometer, more specifically about 0.5 micrometer.

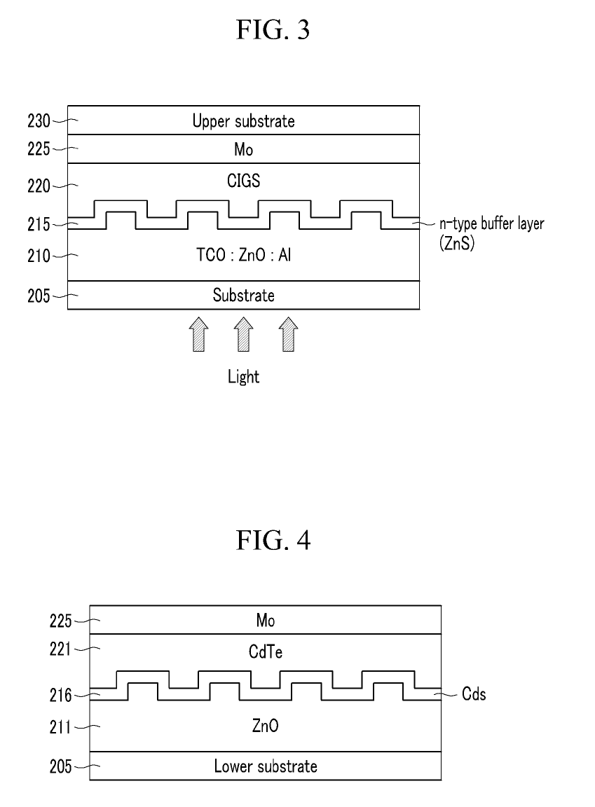

According to an embodiment, a first grating 15 may be disposed on the first electrode 10. The first grating 15 may increase a light absorbing area, thereby improving the luminous efficiency of the solar cell. Alternatively, as illustrated in FIG. 2, a second grating 15′ may be disposed on a second electrode 25. In an embodiment, a grating may be disposed on one of the first electrode 10 and the second electrode 25, which is adjacent to a location on which light is incident. As further disclosed above, the photoelectric efficiency may be increased by lengthening the path of light from the outside by disposing a grating on an electrode. Although not shown in the drawings, in another embodiment, a grating may be disposed on both the first electrode 10 and the second electrode 25.

The photoelectric conversion layer 20 may comprise a silicon material, a compound semiconductor material, an organic material, or the like or a mixture thereof. Solar cells may be categorized as an inorganic solar cell, which comprises an inorganic material, such as silicon or a compound semiconductor, or an organic solar cell, which comprises an organic material, according to the material of the photoelectric conversion layer 20. Examples of organic solar cells include dye sensitized solar cells and organic polymer solar cells. A solar cell according to an embodiment may be an inorganic or an organic solar cell.

The photoelectric conversion layer 20 may have a semiconductor P-N junction structure or a PIN junction structure. Thus, the photoelectric conversion layer 20 may include a P-type semiconductor layer and an N-type semiconductor layer, and an intrinsic semiconductor layer may be interposed between the P-type semiconductor layer and the N-type semiconductor layer.

If the photoelectric conversion layer 20 comprises a compound semiconductor, it may comprise a material selected from the group consisting of copper indium gallium selenide (“CIGS”), copper indium selenide (“CIS”), copper gallium selenide (“CGS”), CdTe, and the like and mixtures thereof. For example, the photoelectric conversion layer 20 may comprise a material selected from the group consisting of CdTe, CuInSe2, Cu(In,Ga)Se2, Cu(In,Ga)(Se,S)2, Ag(InGa)Se2, Cu(In,Al)Se2, CuGaSe2 and the like and mixtures thereof.

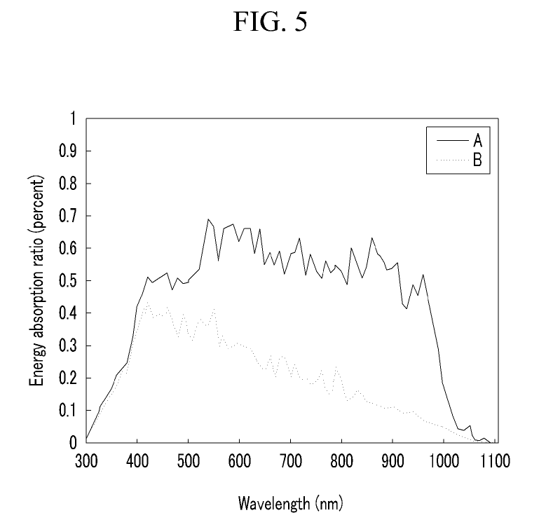

FIG. 3 illustrates a CIGS solar cell in which a photoelectric conversion layer comprises a CIGS compound. The CIGS solar cell includes a lower substrate 205, a transparent conductive oxide (“TCO”) layer 210, which may comprise ZnO:Al, a ZnS layer 215, a CIGS layer 220, a Mo layer 225 and an upper substrate 230. The CIGS layer, which is used as a P-type semiconductor, and a ZnO:Al layer, which is used as an N-type semiconductor, form a P-N junction. When the ZnO:Al layer is an N-type semiconductor, the ZnO:Al layer may have a function corresponding to the first electrode 10 of FIG. 1 or 2. The ZnS layer may be used as a buffer layer, which has a band gap between that of the P-type semiconductor and the N-type semiconductor, to form a junction between the P-type semiconductor and the N-type semiconductor. Also, in the CIS solar cell, a CuInSe2 layer, which is a P-type semiconductor, and a ZnS thin film, which is an N-type semiconductor, form a P-N junction. An N-type buffer layer may comprise a material selected from a group consisting of CdS, Zn(O,S,OH), In(OH)xSy, ZnInxSey, ZnSe, and the like and mixtures thereof. The exemplary embodiments are not limited to the above examples of compound semiconductor solar cells.

The photoelectric conversion layer 20 may have a tandem structure.

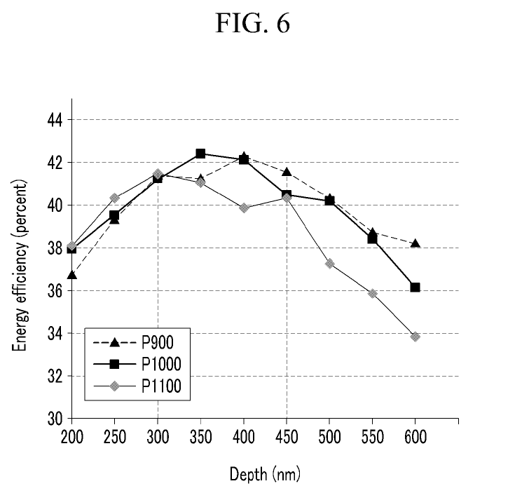

FIG. 4 illustrates a CdTe solar cell in which a photoelectric conversion layer comprises a CdTe compound. The CdTe solar cell may include a lower substrate 205, a ZnO layer 211, a CdS layer 216, a CdTe layer 221 and a Mo layer 225. In an embodiment, the ZnO layer may correspond to a first electrode, the CdS layer may be used as an N-type buffer layer, the CdTe layer may be used as the photoelectric conversion layer and the Mo layer may correspond to a second electrode.

According to the above embodiments, a solar cell may comprise a silicon material, a compound semiconductor material or an organic material, and disposing a grating on at least one of a first electrode and a second electrode increases the luminous efficiency of the solar cell.

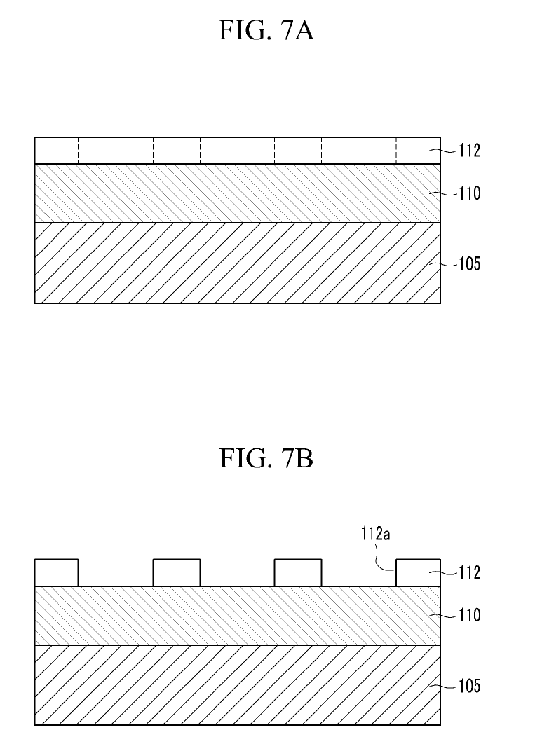

FIG. 5 is a graph comparing an embodiment of a solar cell having a grating with a solar cell not having a grating in terms of an energy absorption ratio (percent) versus a wavelength of light in nanometers (nanometers, nm). Plot A in FIG. 5 illustrates the energy absorption ratio of the solar cell having a grating, and plot B illustrates the energy absorption ratio of the solar cell not having a grating. Referring to FIG. 5, the energy absorption ratio of the solar cell having a grating is higher than that of the solar cell not having a grating.

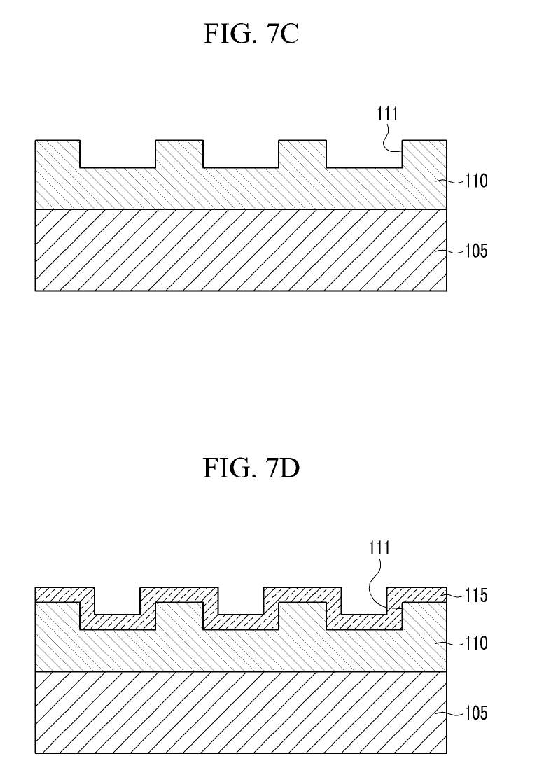

FIG. 6 is a graph illustrating energy efficiency (percent, %) versus depth (nm), thus illustrating the relationship between an energy efficiency and the depth d of a grating included in an embodiment of a solar cell, according to a period P of the grating (see FIG. 1). In FIG. 6, P900 refers to a solar cell having a grating with a period of 900 nm, P1000 refers to a solar cell having a grating with a period of 1000 nm and P1100 refers to a solar cell having a grating with a period of 1100 nm.

Table 1 illustrates the energy absorption ratio as a function of the depth d of the grating (nm) and the period (“P”) of the grating (nm).

TABLE 1

| Depth | Period (nm) | | | | | | | | |
|---|---|---|---|---|---|---|---|---|---|
| (nm) | 600 | 700 | 800 | 900 | 1000 | 1100 | 1200 | 1300 | 1400 |
| 200 | 32.00 | 34.90 | 36.20 | 38.10 | 37.95 | 36.75 | 35.25 | 33.65 | 32.80 |
| 250 | 33.80 | 36.10 | 38.55 | 40.30 | 39.55 | 39.35 | 37.65 | 35.95 | 34.95 |
| 300 | 33.50 | 36.50 | 38.15 | 41.45 | 41.15 | 41.35 | 38.60 | 37.55 | 35.60 |
| 350 | 33.65 | 36.60 | 37.85 | 41.00 | 42.40 | 41.25 | 39.50 | 37.95 | 36.95 |
| 400 | 33.05 | 34.70 | 37.60 | 39.85 | 42.10 | 42.25 | 39.75 | 37.85 | 36.50 |
| 450 | 32.60 | 33.90 | 35.60 | 40.30 | 40.40 | 41.50 | 39.15 | 38.35 | 36.75 |
| 500 | 31.15 | 33.10 | 34.10 | 37.20 | 40.15 | 40.25 | 38.85 | 37.25 | 36.25 |
| 550 | 30.85 | 31.55 | 33.10 | 35.80 | 38.45 | 38.70 | 37.60 | 36.70 | 36.10 |
| 600 | 29.05 | 30.80 | 31.55 | 33.80 | 36.15 | 38.20 | 37.55 | 35.80 | 34.45 |

Referring to FIG. 6, when the depth d of the grating increases, the energy efficiency gradually increases but after a selected length of time, the energy efficiency begins to gradually decrease. According to an embodiment, the energy absorption ratio may be about 20 percent (%) to about 60%, specifically about 30% to about 50%, more specifically about 40% or more and the depth d of the grating may about 200 nm to about 600 nm, specifically about 300 nm to about 450 nm, more specifically about 350 nm to about 400 nm. Referring to Table 1, the period P of the grating may be about 600 nm to about 1400 nm, specifically about 900 nm to about 1100 nm, more specifically about 1000 nm so that the energy absorption ratio may be about 40%. In an embodiment, when the period P of the grating is 900 nm and the depth d of the grating is 400 nm, the energy absorption ratio is about 39.85%, which is about 40%.

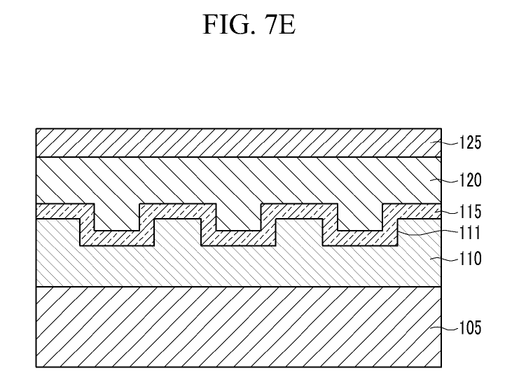

An embodiment of a method of fabricating a solar cell will now be further described with reference to FIGS. 7A to 7E.

Referring to FIG. 7A, a first electrode 110 is disposed on a substrate 105, and a photoresist 112 is applied onto the first electrode 110. Next, referring to FIG. 7B, a pattern 112a corresponding to a grating is disposed on the photoresist 112 using a photolithography process. Next, referring to FIG. 7C, a grating 111 is obtained by etching the first electrode 110 according to the pattern 112a, and then the photoresist 112 is removed. Next, referring to FIG. 7D, a buffer layer 115 is disposed on the first electrode 110. Next, referring to FIG. 7E, a photoelectric conversion layer 120 and a second electrode 125 are sequentially disposed on the buffer layer 115. Although the solar cell according to an embodiment has the buffer layer 115, in another embodiment the photoelectric conversion layer 120 may be directly formed on the first electrode 110 without the buffer layer 115. Also, in an embodiment, the substrate 105, the first electrode 110, the buffer layer 115, the photoelectric conversion layer 120 and the second electrode 125 are sequentially disposed, and in another embodiment they may be disposed in the reverse order.

In the solar cells according to the above embodiments, a grating is disposed on an electrode layer in order to increase the path of light, thereby increasing the energy absorption ratio.

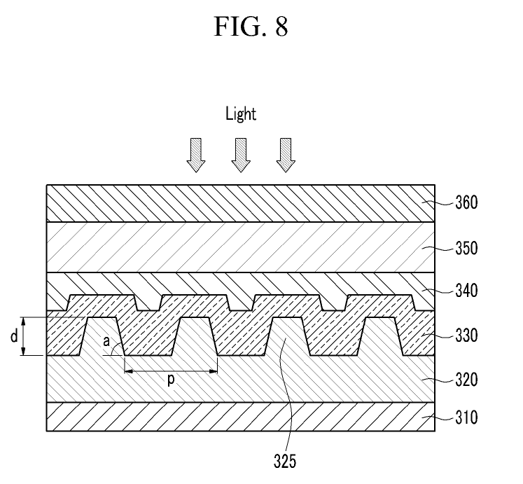

FIG. 8 is a cross-sectional view of a solar cell according to another exemplary embodiment.

Referring to FIG. 8, a first electrode 320 is disposed on a substrate 310. The first electrode 320 may comprise a reflective conductive material such as molybdenum (Mo), copper (Cu) or aluminum (Al).

The first electrode 320 includes a grating 325. The grating 325 comprises a protrusion, which comprises an oblique side surface. An inclination angle a shown in FIG. 8 may be about 10 to about 80 degrees, specifically about 20 to about 70 degrees, more specifically about 30 to about 60 degrees. In another embodiment, the inclination angle a may be less than about 10 degrees if the fabrication process thereof allows. Since a reflection angle is increased as the inclination angle is decreased, an amount of light absorption is increased.

A depth d of the grating 325 may be about 100 nm to about 800 nm, specifically about 250 nm to about 600 nm, more specifically about 300 nm to about 500 nm. A period p of the grating 325 may be about 600 nm to about 2000 nm, specifically about 800 nm to about 1800 nm, more specifically about 1000 nm to about 1600 nm.

A photoelectric conversion layer is disposed on the first electrode 320. The photoelectric conversion layer 330 may comprise one of a silicon-based, a compound semiconductor-based, or an organic material-based photoelectric conversion layer. The solar cell may be an inorganic solar cell, and comprise an inorganic material such as silicon or a compound semiconductor, or an organic solar cell, and include an organic material, such as a dye-sensitized solar cell or an organic polymer solar cell, according to a material of the photoelectric conversion layer 330. The solar cell can be applied to either the inorganic solar cell or the organic solar cell, or both.

The photoelectric conversion layer 330 may have a semiconductor PN-junction or PIN-junction structure. Therefore, the photoelectric conversion layer 330 may include a p-type semiconductor layer and an n-type semiconductor layer, and an intrinsic semiconductor layer may be provided between the p-type semiconductor layer and the n-type semiconductor layer.

When the photoelectric conversion layer 330 comprises a compound semiconductor, at least one of CIGS, CIS, CGS and CdTe may be used. For example, the photoelectric conversion layer 330 may comprise at least one material selected from a group consisting of CdTe, CuInSe2, Cu(In,Ga)Se2, Cu(In,Ga) (Se,S)2, Ag(InGa)Se2, Cu(In,Al)Se2 and CuGaSe2.

A buffer layer 340 is disposed on the photoelectric conversion layer 330. The buffer layer 340 may be disposed between the PN junction to buffer a difference a p-type semiconductor and an n-type semiconductor and an energy band gap. Therefore, an energy band gap of a material used as the buffer layer 340 may have a value between that of the n-type and p-type semiconductors. The buffer layer 340 may comprise ZnS, CdS, Zn(O,S,OH), In(OH)xSy, ZnInxSey, ZnSe or a combination comprising at least one of the foregoing.

A second electrode 350 is disposed on the buffer layer 340. The second electrode 350 may comprise a transparent conductive oxide. The second electrode 350 may comprise one of ITO, IZO, ZnO, GAZO, ZnMgO or SnO2.

A transparent upper substrate 360 may be formed (e.g., disposed) on the second electrode 350. As shown in FIG. 8, light enters through the transparent upper substrate 360, and the grating 325 is formed (e.g., disposed) at the first electrode and disposed a distance in an incident direction of the light.

The light entering through the transparent upper substrate 360 may be mostly absorbed by the photoelectric conversion layer 330, and some of the light may pass through the photoelectric conversion layer 330 without being absorbed. As further disclosed above, light which is not absorbed by the photoelectric conversion layer 330, and thus passes therethrough, may be transmitted to the photoelectric conversion layer 330 again by reflection of the first electrode 320. In an embodiment, the grating 325 formed (e.g., disposed) in (e.g., on) the first electrode 320 increases reflectivity of the passed light to thereby increase light efficiency of the solar cell.

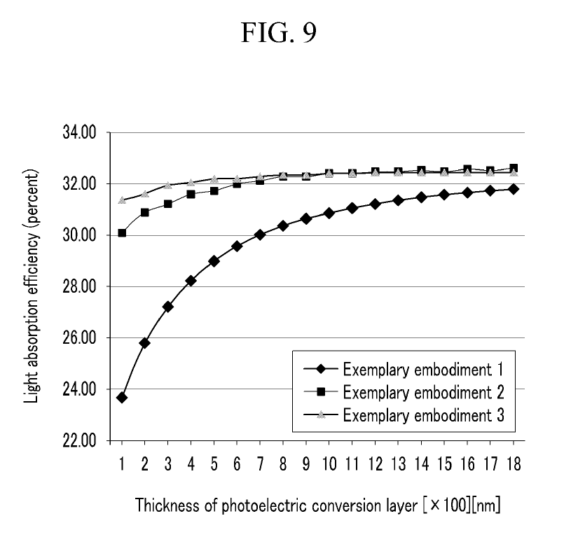

FIG. 9 is a graph illustrating a light absorption efficiency (percent) according to the thickness of a photoelectric conversion layer (hundreds of nanometers) (e.g., light absorbing layer) of solar cells, Exemplary embodiments 2 and 3 having a grating and Exemplary embodiment 1 not having a grating.

In the solar cells corresponding to FIG. 9, a CIGS compound is used as a photoelectric conversion layer. Exemplary embodiment 1 shows a solar cell which does not have a grating, Exemplary embodiment 2 shows a solar cell having a grating formed in a reflective electrode layer, and Exemplary embodiment 3 shows a solar cell having gratings formed in a reflective electrode layer and a transparent electrode layer.

The thickness of the photoelectric conversion layer comprising the CIGS compound can have a selected thickness, and when the thickness of the photoelectric conversion layer is reduced, an area for absorbing light is decreased, decreasing light efficiency. However, like the solar cell according to the exemplary embodiment, when the grating is formed in (e.g., disposed on) a reflective electrode layer (e.g., an electrode layer comprising molybdenum), the light efficiency is not significantly decreased even though the thickness of the photoelectric conversion layer is decreased.

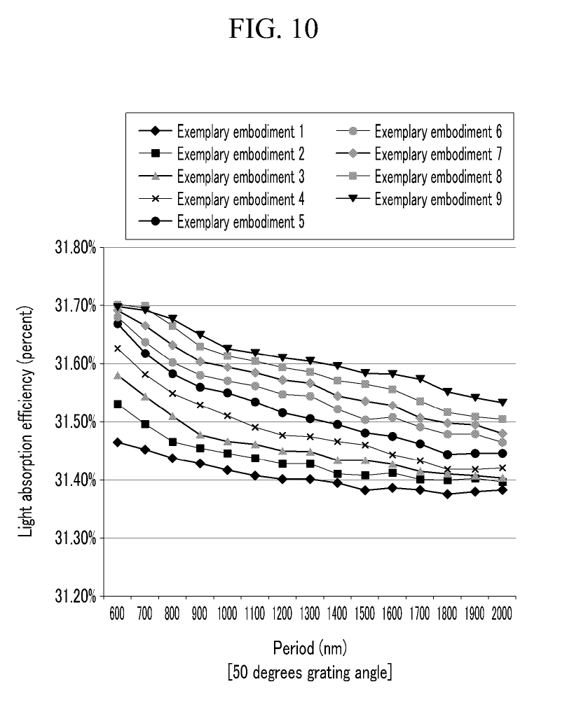

FIG. 10 is a graph illustrating a light absorption according to a period of a photoelectric conversion layer in an embodiment in which an inclination angle of a side surface of a grating is 50 degrees. In addition, Table 2 shows data corresponding to the graph of FIG. 10, and shows light absorption efficiency with respect to the depth and the period of the grating.

TABLE 2

| | Depth | | | | | | | | |
|---|---|---|---|---|---|---|---|---|---|
| Period | 200 | 250 | 300 | 350 | 400 | 450 | 500 | 550 | 600 |
| 600 | 31.47% | 31.53% | 31.58% | 31.63% | 31.67% | 31.68% | 31.69% | 31.70% | 31.70% |
| 700 | 31.45% | 31.50% | 31.54% | 31.58% | 31.62% | 31.64% | 31.67% | 31.70% | 31.69% |
| 800 | 31.44% | 31.47% | 31.51% | 31.55% | 31.58% | 31.60% | 31.63% | 31.67% | 31.68% |
| 900 | 31.43% | 31.45% | 31.48% | 31.53% | 31.56% | 31.58% | 31.60% | 31.63% | 31.65% |
| 1000 | 31.42% | 31.45% | 31.47% | 31.51% | 31.55% | 31.57% | 31.59% | 31.61% | 31.63% |
| 1100 | 31.41% | 31.44% | 31.46% | 31.49% | 31.53% | 31.56% | 31.58% | 31.61% | 31.62% |
| 1200 | 31.40% | 31.43% | 31.45% | 31.48% | 31.52% | 31.55% | 31.57% | 31.60% | 31.61% |
| 1300 | 31.40% | 31.43% | 31.45% | 31.47% | 31.51% | 31.54% | 31.57% | 31.59% | 31.61% |
| 1400 | 31.40% | 31.41% | 31.43% | 31.47% | 31.50% | 31.52% | 31.55% | 31.57% | 31.60% |
| 1500 | 31.38% | 31.41% | 31.43% | 31.46% | 31.48% | 31.50% | 31.54% | 31.57% | 31.58% |
| 1600 | 31.39% | 31.41% | 31.43% | 31.44% | 31.48% | 31.51% | 31.53% | 31.56% | 31.58% |
| 1700 | 31.38% | 31.40% | 31.42% | 31.43% | 31.46% | 31.49% | 31.50% | 31.54% | 31.57% |
| 1800 | 31.38% | 31.40% | 31.41% | 31.42% | 31.44% | 31.48% | 31.50% | 31.52% | 31.55% |
| 1900 | 31.38% | 31.40% | 31.41% | 31.42% | 31.45% | 31.48% | 31.49% | 31.51% | 31.54% |
| 2000 | 31.38% | 31.40% | 31.40% | 31.42% | 31.44% | 31.46% | 31.48% | 31.50% | 31.53% |

Referring to FIG. 10, the light efficiency is increased as the period of the grating is decreased. When the period of the grating is decreased, a reflection angle of a light passing through a photoelectric conversion layer and then reflected by a reflective electrode layer is increased, and therefore the amount of light reabsorbed by the photoelectric conversion layer is increased so that the light efficiency can be increased.

In FIG. 10, Exemplary embodiment 1 to Exemplary embodiment 9 respectively correspond to embodiments in which the depths of the gratings are 200 nm, 250 nm, 300 nm, 350 nm, 400 nm, 450 nm, 500 nm, 550 nm or 600 nm.

The depth of the grating may be about 100 nm to about 800 nm, specifically about 250 nm to about 600 nm, more specifically about 300 nm to about 500 nm to provide a light efficiency of more than 31.50 percent (%). In addition, referring to Table 2, the period of the grating may be selected to be about 600 nm to about 2000 nm, specifically about 800 nm to about 1800 nm, more specifically about 1000 nm to about 1600 nm to provide a light efficiency of more than 31.50%.

FIG. 10 and Table 2 show that the light efficiency is increased as the depth of the grating is increased and the light efficiency is also increased as the period of the grating is decreased. Although it is not shown in Table 2, because the light efficiency is increased as the depth of the grating is increased, in another embodiment, the depth of the grating may be greater than about 600 nm. In addition, although it is not shown in Table 2, the period of the grating may be less than about 600 nm, and the light efficiency is increased as the period of the grating is decreased.

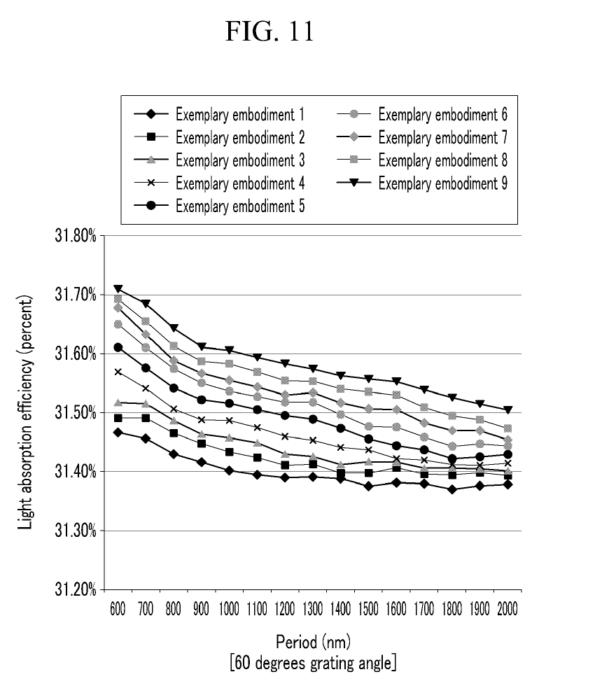

FIG. 11 is a graph illustrating light absorption efficiency according to a period of a photoelectric conversion layer (nanometers) in an embodiment in which an inclination angle of a side surface of a grating is 60 degrees. In addition, Table 3 shows data corresponding to the graph of FIG. 11, and shows light efficiency according to the depth and the period of the grating.

TABLE 3

| | Depth | | | | | | | | |
|---|---|---|---|---|---|---|---|---|---|
| Period | 200 | 250 | 300 | 350 | 400 | 450 | 500 | 550 | 600 |
| 600 | 31.47% | 31.49% | 31.52% | 31.57% | 31.61% | 31.65% | 31.68% | 31.69% | 31.71% |
| 700 | 31.46% | 31.49% | 31.52% | 31.54% | 31.58% | 31.61% | 31.63% | 31.66% | 31.69% |
| 800 | 31.43% | 31.47% | 31.49% | 31.51% | 31.54% | 31.57% | 31.59% | 31.61% | 31.64% |
| 900 | 31.42% | 31.45% | 31.46% | 31.49% | 31.52% | 31.55% | 31.57% | 31.59% | 31.61% |
| 1000 | 31.40% | 31.43% | 31.46% | 31.49% | 31.52% | 31.54% | 31.56% | 31.58% | 31.61% |
| 1100 | 31.39% | 31.42% | 31.45% | 31.48% | 31.51% | 31.53% | 31.54% | 31.57% | 31.59% |
| 1200 | 31.39% | 31.41% | 31.43% | 31.46% | 31.50% | 31.52% | 31.53% | 31.55% | 31.58% |
| 1300 | 31.39% | 31.41% | 31.43% | 31.45% | 31.49% | 31.52% | 31.53% | 31.55% | 31.57% |
| 1400 | 31.39% | 31.40% | 31.41% | 31.44% | 31.47% | 31.50% | 31.52% | 31.54% | 31.56% |
| 1500 | 31.38% | 31.40% | 31.42% | 31.44% | 31.46% | 31.48% | 31.51% | 31.54% | 31.56% |
| 1600 | 31.38% | 31.41% | 31.42% | 31.42% | 31.44% | 31.48% | 31.51% | 31.53% | 31.55% |
| 1700 | 31.38% | 31.40% | 31.41% | 31.42% | 31.44% | 31.46% | 31.48% | 31.51% | 31.54% |
| 1800 | 31.37% | 31.39% | 31.41% | 31.41% | 31.42% | 31.44% | 31.47% | 31.50% | 31.53% |
| 1900 | 31.38% | 31.40% | 31.41% | 31.41% | 31.43% | 31.45% | 31.47% | 31.49% | 31.52% |
| 2000 | 31.38% | 31.39% | 31.40% | 31.41% | 31.43% | 31.44% | 31.45% | 31.47% | 31.50% |

Referring to FIG. 11, the light efficiency is increased as the period of the grating is decreased. When the period of the grating is decreased, a reflection angle of a light passing through a photoelectric conversion layer and then reflected by a reflective electrode layer is increased, and therefore the amount of light reabsorbed by the photoelectric conversion layer is increased so that the light efficiency can be increased.

In FIG. 11, Exemplary embodiment 1 to Exemplary embodiment 9 respectively correspond to embodiments in which the depths of the gratings are 200 nm, 250 nm, 300 nm, 350 nm, 400 nm, 450 nm, 500 nm, 550 nm or 600 nm.

The depth of the grating may be about 300 nm to about 600 nm, specifically 400 nm to about 500 nm, more specifically about 450 nm to provide a light efficiency of more than 31.50%. In addition, referring to Table 3, the period of the grating may be selected to be about 600 nm to about 2000 nm, specifically about 800 nm to about 1800 nm, more specifically about 1000 nm to about 1600 nm to provide a light efficiency of more than 31.50%.

FIG. 11 and Table 3 show that the light efficiency is increased as the depth of the grating is increased and the light efficiency is also increased as the period of the grating is decreased. Although it is not shown in Table 3, because the light efficiency is increased as the depth of the grating is increased, the depth of the grating may be greater than about 600 nm. In addition, although it is not shown in Table 3, the period of the grating may be less than about 600 nm because the light efficiency is increased as the period of the grating is decreased.

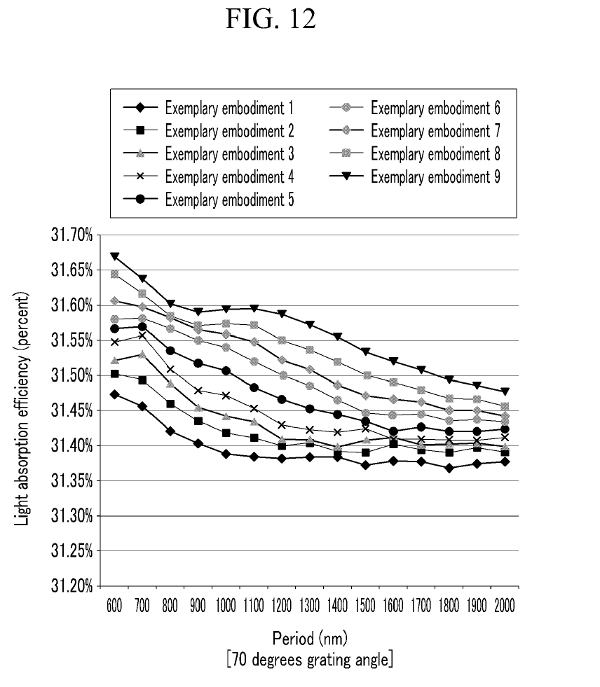

FIG. 12 is a graph illustrating light absorption efficiency (percent) according to a period of a photoelectric conversion layer (nanometers) in an embodiment in which an inclination angle of a side surface of a grating is 70 degrees. In addition, Table 4 shows data corresponding to the graph of FIG. 12 and shows light absorption efficiency according to the depth and the period of the grating.

TABLE 4

| | Depth | | | | | | | | |
|---|---|---|---|---|---|---|---|---|---|
| Period | 200 | 250 | 300 | 350 | 400 | 450 | 500 | 550 | 600 |
| 600 | 31.47% | 31.50% | 31.52% | 31.55% | 31.57% | 31.58% | 31.61% | 31.64% | 31.67% |
| 700 | 31.46% | 31.49% | 31.53% | 31.56% | 31.57% | 31.58% | 31.60% | 31.62% | 31.64% |
| 800 | 31.42% | 31.46% | 31.49% | 31.51% | 31.53% | 31.57% | 31.58% | 31.58% | 31.60% |
| 900 | 31.40% | 31.43% | 31.45% | 31.48% | 31.52% | 31.55% | 31.56% | 31.57% | 31.59% |
| 1000 | 31.39% | 31.42% | 31.44% | 31.47% | 31.51% | 31.54% | 31.56% | 31.57% | 31.59% |
| 1100 | 31.38% | 31.41% | 31.43% | 31.45% | 31.48% | 31.52% | 31.55% | 31.57% | 31.60% |
| 1200 | 31.38% | 31.40% | 31.41% | 31.43% | 31.46% | 31.50% | 31.52% | 31.55% | 31.59% |
| 1300 | 31.38% | 31.40% | 31.41% | 31.42% | 31.45% | 31.49% | 31.51% | 31.54% | 31.57% |
| 1400 | 31.38% | 31.39% | 31.40% | 31.42% | 31.45% | 31.47% | 31.49% | 31.52% | 31.56% |
| 1500 | 31.37% | 31.39% | 31.41% | 31.42% | 31.43% | 31.45% | 31.47% | 31.50% | 31.53% |
| 1600 | 31.38% | 31.40% | 31.41% | 31.41% | 31.42% | 31.44% | 31.47% | 31.49% | 31.52% |
| 1700 | 31.38% | 31.39% | 31.40% | 31.41% | 31.43% | 31.45% | 31.46% | 31.48% | 31.51% |
| 1800 | 31.37% | 31.39% | 31.40% | 31.41% | 31.42% | 31.44% | 31.45% | 31.47% | 31.49% |
| 1900 | 31.37% | 31.40% | 31.40% | 31.41% | 31.42% | 31.44% | 31.45% | 31.47% | 31.49% |
| 2000 | 31.38% | 31.39% | 31.40% | 31.41% | 31.42% | 31.43% | 31.44% | 31.46% | 31.48% |

Referring to FIG. 12, the light efficiency is increased as the period of the grating is decreased. When the period of the grating is decreased, the light is bent with a large angle so that the amount of light absorption is increased, thereby increasing the light efficiency. In FIG. 12, Exemplary embodiment 1 to Exemplary embodiment 9 respectively correspond to embodiments in which the depths of the grating are 200 nm, 250 nm, 300 nm, 350 nm, 400 nm, 450 nm, 500 nm, 550 nm or 600 nm.

The depth of the grating may be about 250 nm to about 600 nm, more specifically about 300 nm to about 500 nm to provide a light efficiency of more than 31.50%. In addition, referring to Table 3, the period of the grating may be selected to be about 600 nm to about 1700 nm, specifically about 700 nm to about 1600 nm, more specifically about 800 nm to about 1500 nm to provide a light efficiency of more than 31.50%.

FIG. 12 and Table 4 show that the light efficiency is increased as the depth of the grating is increased and the light efficiency is also increased as the period of the grating is decreased. Although it is not shown in Table 4, because the light efficiency is increased as the depth of the grating is increased, the depth of the grating may be greater than about 600 nm according to another exemplary embodiment. In addition, although it is not shown in Table 4, the period of the grating may be less than about 600 nm according to another exemplary embodiment because the light efficiency is increased as the period of the grating is decreased.

Table 4 shows that the light efficiency is increased when the angle of the grating is about 50 degrees. Since a light scattering angle is increased when the grating has a perpendicular shape (e.g., a side surface which is substantially perpendicular to a front surface of the first electrode) rather than having a tapered shape, the side surface of the grating may be oblique.

A result of measurement of light absorption efficiency of exemplary solar cells having the grating angle selected to be 50 to 70 degrees shows that the light efficiency was highest when the grating angle is 50 degrees, and the side surface of the grating may be formed (e.g., disposed) to be tapered if the process allows. In other words, in an embodiment the grating may have a grating angle of less than about 70 degrees, rather than having a perpendicular shape.

It should be understood that the exemplary embodiments described herein should be considered in a descriptive sense only and not for purposes of limitation. Descriptions of features, advantages or aspects within each embodiment should be considered as available for other similar features or aspects in other embodiments.

What is claimed is:

1. A solar cell, comprising:
a substrate;
a first electrode disposed on the substrate;
a photoelectric conversion layer disposed on the first electrode; and
a second electrode disposed on the photoelectric conversion layer,
wherein a grating is disposed on at least one of the first electrode and the second electrode.

2. The solar cell of claim 1, wherein the grating has a depth of about 300 nanometers to about 450 nanometers.

3. The solar cell of claim 2, wherein a period of the grating is about 900 nanometers to about 1100 nanometers.

4. The solar cell of claim 1, wherein the photoelectric conversion layer comprises a compound semiconductor.

5. The solar cell of claim 4, wherein the photoelectric conversion layer comprises a material selected from the group consisting of CdTe, CuInSe₂, Cu(In,Ga)Se₂, Cu(In,Ga)(Se,S)₂, Ag(InGa)Se₂, Cu(In,Al)Se₂, CuGaSe₂ and a combination comprising at least one of the foregoing.

6. The solar cell of claim 1, wherein the first electrode comprises a transparent conductive oxide.

7. The solar cell of claim 6, wherein the first electrode comprises at least one of indium tin oxide, indium zinc oxide, ZnO, gallium zinc oxide, ZnMgO and SnO2.

8. The solar cell of claim 6, wherein the second electrode comprises a transparent conductive oxide, a metal or a combination comprising at least one of the foregoing.

9. The solar cell of claim 8, wherein the metal comprises at least one of Mo, Al, Cu, Ti, Au, Pt, Ag and Cr.

10. The solar cell of claim 1, wherein the photoelectric conversion layer has a tandem structure.

11. The solar cell of claim 1, wherein a side surface of the grating has an oblique shape.

12. The solar cell of claim 11, wherein an inclination angle formed by the side surface of the grating and a surface of the first electrode or the second electrode is about 10 to about 70 degrees.

13. The solar cell of claim 12, wherein the first electrode comprises a reflective conductive metal.

14. The solar cell of claim 13, wherein the first electrode comprises at least one of Mo, Cu and Al.

15. The solar cell of claim 14, wherein the depth of the grating is at least about 250 nm.

16. The solar cell of claim 15, wherein a period of the grating is less than about 2000 nm.
